(19) United States
(12) Patent Application Publication
(10) Pub. No.: US 2013/0258604 A1
(43) Pub. Date: Oct. 3, 2013

(54) SLIDEABLE TRAY WITH CORD RETENTION FEATURE

(71) Applicant: Jonathan Joseph Quijano, Ann Arbor, MI (US)

(72) Inventor: Jonathan Joseph Quijano, Ann Arbor, MI (US)

(73) Assignee: Toyota Motor Engineering & Manufacturing, Erlanger, KY (US)

(21) Appl. No.: 13/434,930

(22) Filed: Mar. 30, 2012

(51) Int. Cl. H05K 7/14; B60R 7/04; H01R 43/00; H05K 7/18

(52) U.S. Cl. 361/725; 211/26; 296/24.34; 29/825

(57) ABSTRACT

A moveable tray assembly having a cable retention feature. The moveable tray assembly can include a console with a moveable tray that has a first end, a second end, and a planar portion extending between the first end and the second end. The planar portion can be dimensioned for a portable electronic device to lay flat thereon and thus hold the device. The second end of the moveable panel can have a slot extending towards the first end a predefined distance. The slot has a width and the width is dimensioned such that an electronic cable can fit through the slot, but a connector end of the electronic cable cannot fit through the slot.

### FIELD OF THE INVENTION

The present invention is related to a moveable tray assembly, and in particular, a moveable tray assembly that can hold or retain an electronic cable with a connector end that can be connected to a portable electronic device.

### BACKGROUND OF THE INVENTION

The-use of moveable and/or slideable trays is known. In some instances, the tray can cover a compartment which can be used for storage of various items. In addition, a tray and the compartment can be part of a console, e.g. a center console in a motor vehicle. It is appreciated that such slideable trays can have objects placed thereon and thus can serve a function in addition to covering and uncovering the compartment underneath.

In the event that a moveable tray is used to hold a portable electronic device, it can also be desirable to charge the electronic device while the device is located on the tray. However, when an electronic cable extends from an electrical outlet located within the compartment to the portable electronic device located on top of the tray, a user can be inconvenienced by having to open the tray in order to get access to the cable and then having to close the tray in order to place the portable electronic device thereon. In addition, while the portable electronic device is connected to the electrical outlet via the electronic cable, the moveable tray can be prevented from being located in a fully closed position since the electrical outlet is within the compartment and the cable must extend from inside the compartment to outside the compartment. Therefore, a moveable tray that has a cable retention feature that holds at least a portion of an electronic cable outside of a compartment that is underneath the tray such that it can be easily grasped by an individual without having to open the tray and look within the compartment would be desirable.

### SUMMARY OF THE INVENTION

A moveable tray assembly with a cable retention feature is provided. The moveable tray assembly can include a console with a moveable tray that has a first end, a second end, and a planar portion extending between the first end and the second end. The planar portion can be dimensioned for a portable electronic device to lay flat thereon and thus hold the device, e.g. during operation of a motor vehicle within which the console is located.

The second end of the moveable tray can have a slot extending towards the first end a predefined distance, the slot having a width and the width dimensioned such that an electronic cable can fit therethrough. In some instances, the slot can be part of and/or within a handle with the handle located at the second end. The electronic cable can have a connector end that can be attached or plugged into the portable electronic device and the slot width is such that the connector end cannot fit therethrough. As such, the cable can be placed within the slot, but with the connector end not fitting through the slot, the connector end can be held or retained on top of the moveable tray.

The moveable tray can be a slideable tray that is operable to slide between a closed position and an open position and the console can have a compartment located underneath the slideable tray. The compartment can have an electrical outlet for providing electrical power to a portable electronic device via the electronic cable and/or for receiving electrical signals from the portable electronic device. It is appreciated that the slideable tray can cover or enclose the compartment when it is in the closed position and uncover the compartment when it is in the open position. In addition, the slideable tray can slide in a generally forward and/or upward direction when sliding from the closed position to the open position. For example, the tray can slide up and/or forward into an instrument panel of a motor vehicle. In addition, the slideable tray can be dimensioned such that the portable electronic device can remain on the planar portion when it slides between the closed position and the open position.

A process for electronically connecting the portable electronic device to a motor vehicle is also disclosed, the process including providing the console, slideable tray, and compartment described above. A portable electronic device and an electronic cable having an outlet end and device end are also provided and the outlet end is plugged into the electronic outlet within the compartment. In addition, at least a portion of the electronic cable is placed or slid into the slot of the slideable tray and the device end is located above the slot. The device end is retained or held above the slot and/or slideable tray and may or may not be plugged into the portable electronic device. It is appreciated that the device end can be plugged into the portable electronic device before the cable is placed or slid within the slot and then the portable electronic device with the device end can be placed onto the planar portion of the moveable panel. In either case, the electronic cable passes through the slot and the device end is held above the slot and on top of the slideable tray since the slot and the device end are dimensioned such that the cable cannot completely fall through the slot.

The process can also include unplugging the device end from the portable electronic device and removing the device from the planar portion of the slideable tray. However, the slot prevents the device end of the electronic cable from passing therethrough and thus holds the device end on top of the moveable panel for future use. In this manner, an individual does not have to slide the slideable tray from the closed position towards the open position in order to gain access to the device end of the electronic cable when desired.

### BRIEF DESCRIPTION OF THE DRAWINGS

FIG. 1 is a front view of an instrument panel having a slideable tray according to an embodiment of the present invention;

FIG. 2 is a perspective view of the slideable tray according to an embodiment of the present invention;

FIG. 3 is an enlarged view of a slot in the slideable tray shown in FIG. 2; and

FIG. 4 is a top view of the slot shown in FIG. 3.

### DETAILED DESCRIPTION OF THE PRESENT INVENTION

A moveable tray assembly that has a cable holding or retention feature is disclosed. As such, the moveable tray assembly has use as a component in a motor vehicle.

The moveable tray assembly can include a console with a moveable panel, the moveable panel having a first end, a second end, and a planar portion extending between the first end and the second end. The planar portion can be dimensioned such that a portable electronic device such as a cell phone, smart phone, portable media player, personal digital assistant, and the like can be laid flat thereon and located and/or held during normal operation of a machine in which the moveable panel is located. For example, the console with the moveable panel can be located within a motor vehicle. In addition, the console can be a center console of the motor vehicle.

The second end of the moveable panel can have a slot that extends towards the first end a predefined distance. In addition, the slot can have a width such that an electronic cable can fit or slide therethrough. However, if the electronic cable has a connector end that can be used to connect to a portable electronic device, the slot is dimensioned such that the connector end cannot pass through the slot. As such, the electronic cable can fit and slide within the slot, but the connector end is held and/or retained on a particular side of the moveable panel. In this manner, the moveable panel with the slot retains or holds at least a portion of the electronic cable at a desired location.

The moveable panel can be a slideable tray that is operable to slide between a closed position and an open position. It is appreciated that the panel can have a compartment located underneath and the compartment can have at least one electrical outlet for providing electrical power and/or receiving electronic signals to and/or from a portable electronic device via an electronic cable. As such, the at least one electrical outlet can used for charging a portable electronic device, an auxiliary in-line connection, and the like.

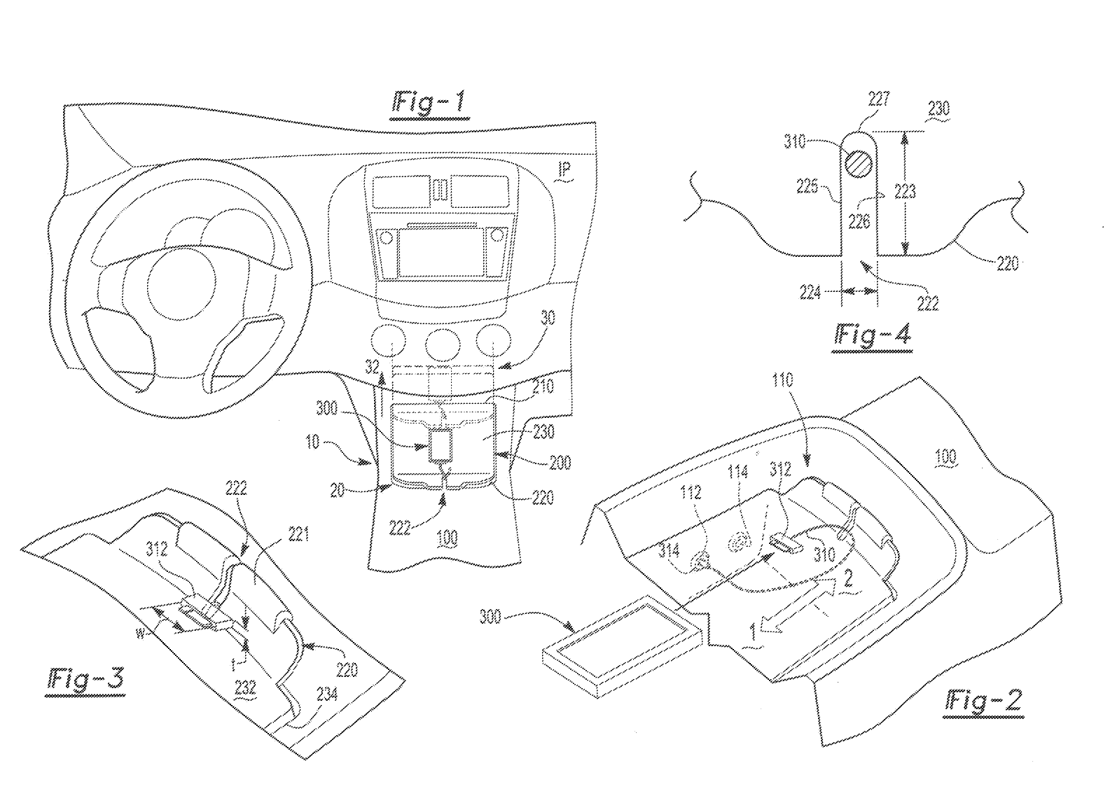

Turning now to FIGS. 1-4, an illustrative example of a moveable tray assembly is shown as part of an interior of a motor vehicle at reference numeral 10. The motor vehicle can have an instrument panel IP and the moveable tray assembly 10 can include a center console 100. In addition, a moveable tray or panel 200 having a first end 210, a second end 220, and a planar portion 230 extending between the first end 210 and the second end 220 can be included: A portable electronic device 300 is shown on the planar portion 230 and the moveable tray 200 can hold the portable electronic device 300 when it is in a closed position 20 and in an open position 30. In addition, the moveable tray 200 can move in a generally forward and/or upward direction 32 when it moves or slides from the closed position 20 to the open position 30. It is appreciated that the moveable tray 200 can also move in a generally opposite direction when moving or sliding from the open position 30 to the closed position 20.

The second end 220 can have a slot 222, the slot 222 having a length 223 and a width 224. The width 224 is greater than an outer dimension of an electronic cable 310 such that the cable 310 can fit and slide within the slot 222. In addition, the slot 222 can have a first side 225 and a second side 226 that extend in a first direction 1 towards the first end 210 of the moveable panel, and a forward end 227 can be located a predefined distance towards the front end 210.

In some instances, the console 100 can have a compartment 110 located underneath the slideable panel 200 when the panel is in the closed position 20. The compartment 110 can have at least one electrical outlet 112, e.g. a rechargeable electrical outlet. In addition, the compartment 110 can have other outlets such as an auxiliary in-line outlet or connection 114.

The electronic cable 310 can have a device end 312 and an outlet end 314. It is appreciated that the outlet end 314 can be designed and/or dimensioned to plug into the outlet 112 or outlet 114 such that electrical power can be provided to the device end and/or electrical signals can be received from the device end 312. The device end 312 can have a width ‘w’ and a thickness ‘t’ that can be greater than the width 224 of the slot 222. As such, and with the cable 310 able to fit within the slot 222, the device end 312 can be held on or above an upper surface 232 of the moveable panel 200 once the cable 310 is placed within the slot 222.

As shown in FIG. 3, the device end 312 can be held above the slot 222 and on or above the top surface 232 even if not plugged into the electronic device 300. As such, ready access to the device end 312 is afforded to a user of the electronic device 300 such that sliding of the panel 200 to gain access to the compartment 110 is not required.

The second end 220 can have a handle 221 that affords for grasping, pushing, and/or pulling of the second end 220 and the slot 222 can extend at least partially through the handle 221. It is appreciated that the slot 222 extends in the forward direction 32 to an extent that the cable 310 can slide up or down through the slot 222 when the moveable panel is in the closed position 20.

The console, moveable panel, and the like can be made from any material known to those skilled in the art, illustratively including polymers, metals, alloys, ceramics, wood, and the like. In addition, it is appreciated from the description above that changes, amendments, etc. will be evident to one skilled in the art without going beyond the scope of the invention. As such, it should be appreciated that the description above is not meant to limit the scope of the invention in any way and that it is the following claims that provide the scope of the invention.

I claim:

1. A moveable tray assembly for holding a portable electronic device and an electronic cable with a connector end to be connected to the portable electronic device, said moveable tray assembly comprising:
a console having a moveable panel with a first end, a second end and a planar portion extending between said first end and said second end, said planar portion dimensioned for the portable electronic device to lay flat thereon;
said second end having a slot extending towards said first end a predefined distance, said slot having a width, said width dimensioned such that the electronic cable can fit therethrough and the connector end cannot fit therethrough, said moveable panel with said slot operable to hold the portable electronic device and the connector end on an upper side of said moveable panel with at least a portion of the electronic cable located on a lower side of said moveable panel.

2. The moveable tray assembly of claim 1, wherein said moveable panel is a slideable panel operable to slide between a closed position and an open position.

3. The moveable tray assembly of claim 2, further comprising a compartment located underneath said panel, said compartment having an electrical outlet for providing electrical power to the portable electronic device through the electronic cable.

4. The moveable tray assembly of claim 3, wherein said slideable panel slides from said closed position in an upward direction to said open position, said compartment being covered by said slideable panel when said slideable panel is in said closed position and uncovered when said slideable panel is in said open position.

5. The moveable tray assembly of claim 4, wherein slideable panel is dimensioned such the portable electronic device can remain on said planar portion when said slideable panel slides between said closed position and said open position.

6. The moveable tray assembly of claim 5, wherein said slot is dimensioned to hold the connector end of the electronic cable on said upper side of said slideable panel when said slideable panel slides between said closed position and said open position and after the portable electronic device has been removed from the planar portion.

7. The moveable tray assembly of claim 6, wherein said electrical outlet is operable for charging the portable electronic device.

8. The moveable tray assembly of claim 7, wherein said compartment has an auxiliary in-line connection.

9. A moveable tray assembly comprising:
a motor vehicle with a center console, said center console having a compartment and a moveable panel covering said compartment when in a closed position and uncovering said compartment when in an open position, said compartment having an electrical outlet, said moveable panel having a front end and back end, said back end having a slot extending a predefined distance towards said front end and providing an opening into said compartment when said moveable panel is in said closed position; and
an electronic cable having an outlet end located under said moveable panel and within said compartment and a device end located above said moveable panel, said electronic cable located within said slot;
said slot having a width, said width greater than a diameter of said electronic cable and less than an outer dimension of said device end, said moveable panel with said slot operable to hold said device end of said electronic cable above said moveable panel when said moveable panel moves between said closed position to said open position.

10. The moveable tray of claim 9, further comprising a portable electronic device on top of said moveable panel with said device in electronic communication therewith.

11. The moveable tray of claim 10, wherein said moveable panel is a slideable panel that is operable to slide between said closed position and said open position.

12. The moveable tray of claim 11, wherein said slideable panel has a planar portion between said front end and said back end, said planar portion dimensioned to hold said portable electronic device when said slideable panel is in said closed position, said open position and when said slideable panel slides between said closed position and said open position.

13. A process for electronically connecting a portable electronic device to a motor vehicle, the process comprising:
providing a portable electronic device;
providing a motor vehicle with a console having:
a compartment with an electrical outlet;
a moveable panel with a first end, a second end and a planar portion extending between the first end and the second end, the planar portion dimensioned for the portable electronic device to lay flat thereon, the moveable panel operable to move between a closed position that covers the compartment and an open position that uncovers the compartment;
the second end having a slot extending towards the first end a predefined distance, the slot having a width such that the electronic cable can fit therethrough and the connector end cannot fit therethrough;
providing an electronic cable having an outlet end and a device end;
plugging the outlet end of the electronic cable into the electrical outlet of the compartment;
placing the electronic cable in the slot with the device end located above the slot;
plugging the device end of the electronic cable into the portable electronic device and placing the electronic device onto the planar portion of the moveable panel

14. The process of claim 13, wherein the moveable panel is in the closed position when the device end of the electronic cable is plugged into the electronic device.

15. The process of claim 14, further including moving the moveable panel from the closed position to the open position with the portable electronic device on the planar portion.

16. The process of claim 13, further including unplugging the device end from the portable electronic device and removing the portable device from the planar portion of the slideable panel, the slot preventing the device end of the electronic cable from passing therethrough and holding the device end on top of the moveable panel for future use.

17. The process of claim 16, wherein the device end of the electronic cable is plugged into the electronic device without having to move the moveable panel from the closed position to the open position.
